(19) United States
(12) Patent Application Publication
(10) Pub. No.: US 2025/0351434 A1
(43) Pub. Date: Nov. 13, 2025

(54) SEMICONDUCTOR DEVICE INCLUDING SOURCE/DRAIN UNIT WITH TUNNEL LAYER AND METHOD FOR MANUFACTURING THE SAME

(71) Applicant: TAIWAN SEMICONDUCTOR MANUFACTURING COMPANY, LTD., Hsinchu (TW)

(72) Inventors: Yen-Chieh HUANG, Hsinchu (TW); Huai-Ying HUANG, Hsinchu (TW); I-Che LEE, Hsinchu (TW); Wei-Gang CHIU, Hsinchu (TW); Yu-Chuan SHIH, Hsinchu (TW); Chun-Chieh LU, Hsinchu (TW); Yu-Ming LIN, Hsinchu (TW)

(73) Assignee: TAIWAN SEMICONDUCTOR MANUFACTURING COMPANY, LTD., Hsinchu (TW)

(21) Appl. No.: 18/662,286

(22) Filed: May 13, 2024

(51) Int. Cl. H01L 29/786; H01L 29/49; H01L 29/66

(52) U.S. Cl. CPC H10D 30/6713; H10D 30/031; H10D 30/6739; H10D 30/6755

(57) ABSTRACT

A semiconductor structure includes a gate electrode, a gate dielectric layer disposed on the gate electrode, a channel disposed on the gate dielectric layer opposite to the gate electrode, and a drain unit and a source unit connected to the channel and spaced apart from each other by the channel. At least one of the drain unit and the source unit includes an electrode, and a tunnel layer disposed between the electrode and the channel so as to adjust a barrier height between the electrode and the channel.

### BACKGROUND

Thin film transistors manufactured using thin film techniques are known to be used in various applications. The thin film transistors may be formed in a front-end-of-line process, or may be embedded in a back-end-of-line interconnect structure, thereby reducing a chip area of an integrated circuit. The thin-film transistors with low current leakage are under continuous development.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic sectional view illustrating a semiconductor device including a semiconductor structure in accordance with some embodiments.

FIGS. 2 to 7 are each a schematic sectional view illustrating the semiconductor structure in accordance with some other embodiments.

FIG. 8 is a diagram showing shift of threshold voltage of the semiconductor structure in accordance with some embodiments, in which a relatively negative value of threshold voltage results from a tunnel layer being omitted from the semiconductor structure, and a relatively positive value (a negative value with a smaller absolute value or a positive value) of the threshold voltage results from the tunnel layer being included in the semiconductor structure.

FIG. 9 is a diagram showing distribution of hydrogen concentration in four samples of the semiconductor structure in accordance with some embodiments, in which three of the samples are each formed with a cap layer disposed on a channel of the semiconductor structure.

FIG. 10 is a diagram showing distribution of hydrogen concentration in three samples of the semiconductor structure in accordance with some embodiments, in which the three samples are respectively formed with three cap layers which have different thicknesses and each of which is disposed on a channel of the semiconductor structure.

FIG. 11 is a flow diagram illustrating a method for manufacturing the semiconductor structure in accordance with some embodiments.

FIGS. 12 to 19 are schematic views showing some intermediate stages of the method depicted in FIG. 11.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “over,” “front,” “back,” “below,” “beneath,” “upper,” “lower,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the terms “about” and “substantially” even if the terms “about” and “substantially” are not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the terms “about” and “substantially,” when used with a value, can capture variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

The term “source/drain unit(s)” or “source/drain portion(s)” may refer to a source or a drain, individually or collectively dependent upon the context.

In some applications, a gate dielectric layer of a thin-film transistor (TFT) may be made of a ferroelectric material, and such thin-film transistor (also referred to as a ferroelectric field-effect transistor (FeFET)) may function as a memory device capable of storing binary data. In the case that the FeFET includes an n-channel (i.e., a channel having an n-type conductivity), the threshold voltage of the FeFET (in an initial state, a programmed state and/or an erased state) may be a negative value, indicating that a current (i.e., current leakage) is present in the n-channel when no voltage is applied. Therefore, in order to reduce the current leakage, the present disclosure provides a semiconductor structure having a relatively positive threshold voltage when an n-channel is included therein, or a semiconductor structure having a relatively negative threshold voltage when a p-channel (i.e., a channel having a p-type conductivity) is included therein.

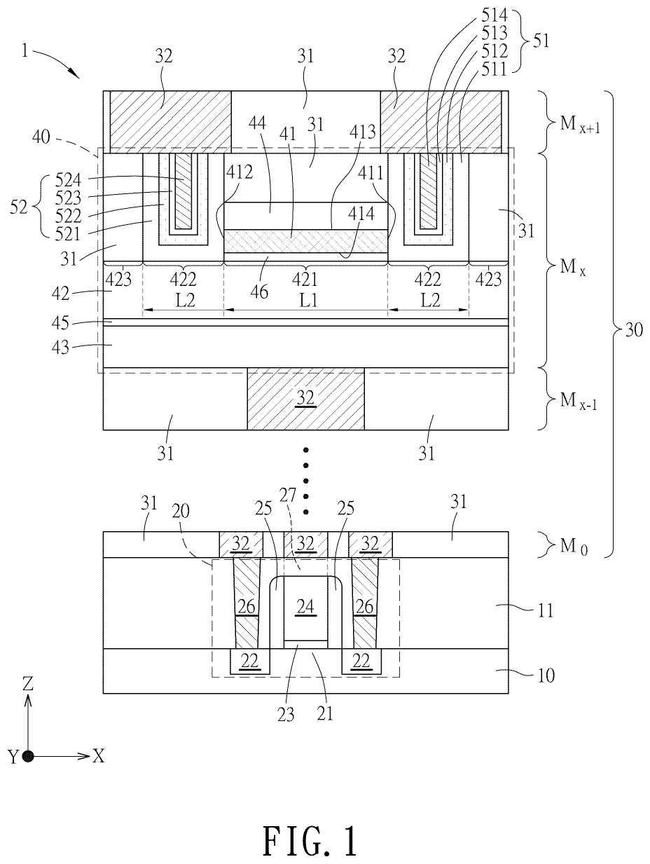

FIG. 1 is a schematic sectional view illustrating a semiconductor device 1 in accordance with some embodiments. The semiconductor device 1 includes a substrate 10, a first semiconductor structure 20 (which serves as, for example, but not limited to, a front-end-of-line (FEOL) transistor), an inter-layer dielectric (ILD) layer 11 disposed on the substrate 10 to cover the first semiconductor structure 20, an interconnect structure 30 disposed on the ILD layer 11, and a second semiconductor structure 40 (which serves as a back-end-of-line (BEOL) transistor) disposed in the interconnect structure 30. It is noted that the second semiconductor structure 40 is not limited to be disposed directly above the first semiconductor structure 20. In some other embodiments, the first semiconductor structure 20 shown in FIG. 1 may be omitted. In such case, the second semiconductor structure 40 may be directly disposed on the substrate 10, or disposed on a buffer layer (not shown) that is formed on the substrate 10 and that is used for improving the film quality of a film to be formed thereon.

In some embodiments, the substrate 10 may include elemental semiconductor materials (such as crystalline silicon, diamond, or germanium), compound semiconductor materials (such as silicon carbide, gallium arsenide, indium arsenide, or indium phosphide), alloy semiconductor materials (such as silicon germanium, silicon germanium carbide, gallium arsenide phosphide, or gallium indium phosphide), or combinations thereof. In some embodiments, the substrate 10 may be a bulk semiconductor substrate, for example, but not limited to, a bulk substrate of silicon, germanium, silicon germanium, or other suitable semiconductor materials (such as the examples described earlier in the same paragraph). In some other embodiments not shown herein, the substrate 10 may be configured as a semiconductor-on-insulator substrate. In some embodiments, the semiconductor material in the substrate 10 may be un-doped, or may be doped with impurities (e.g., n-type impurities or p-type impurities) to form a well portion for the first semiconductor structure 20. In some yet other embodiments, the substrate 10 may be a glass substrate. Other suitable materials and configurations for the substrate 10 are within the contemplated scope of the present disclosure.

In some embodiments, the first semiconductor structure 20 may be a field-effect transistor (FET), and includes a channel 21, two source/drain portions 22 formed at two opposite sides of the channel 21, a gate dielectric layer 23 formed on the channel 21, a gate electrode 24 formed on the gate dielectric layer 23 such that the channel 21 is spaced apart from the gate electrode 24 by the gate dielectric layer 23, and two dielectric spacers 25 formed at two opposite sides of the gate electrode 24. In some embodiments, the first semiconductor structure 20 further includes two source/drain contacts 26 and a gate contact 27 formed in the ILD layer 11 and spaced apart from each other. The source/drain contacts 26 are respectively formed on the source/drain portions 22, and the gate contact 27 is formed on the gate electrode 24. In some embodiments, as shown in FIG. 1, the first semiconductor structure 20 may be configured as a planar FET, in which (i) the source/drain portions 22 are formed in the substrate 10 by an implantation process, and (ii) a portion of the substrate 10, which is located between the source/drain portions 22, serves as the channel 21. The source/drain portions 22 may be doped with impurities to have an n-type conductivity or a p-type conductivity according to the type of the first semiconductor structure 20 (i.e., the source/drain portions 22 have the n-type conductivity when the first semiconductor structure 20 is an n-FET; and the source/drain portions 22 have the p-type conductivity when the first semiconductor structure 20 is a p-FET). In some embodiments, the gate dielectric layer 23 may be made of silicon oxide, and the gate electrode 24 may be made of polycrystalline silicon. In some other embodiments not shown herein, the first semiconductor structure 20 may be configured as a fin-type field-effect transistor (FinFET), or a gate-all-around field-effect transistor (GAAFET). In such case, the gate dielectric layer 23 may include a high dielectric constant (high-k) material, and the gate electrode 24 include a metallic material. Other three-dimensional (3D) transistor structures suitable for the first semiconductor structure 20 are within the contemplated scope of the present disclosure.

In some embodiments, the ILD layer 11 includes a dielectric material. In some embodiments, the dielectric material for forming the ILD layer 11 may have a low dielectric constant, and may include silicon oxynitride, phosphosilicate glass (PSG), borosilicate glass (BSG), borophosphosilicate glass (BPSG), undoped silicate glass (USG), fluorinated silicate glass (FSG), silicon oxycarbide (SiOC), spin-on-glass (SOG), or combinations thereof. Other dielectric materials suitable for the ILD layer 11 are within the contemplated scope of the present disclosure. The interconnect structure 30 includes a plurality of interconnect layers which are sequentially formed on the ILD layer 11. Four of the interconnect layers are exemplarily shown in FIG. 1, and are respectively represented by M₀, Mₓ₋₁, Mₓ, Mₓ₊₁, where x is an integer not less than 2. Other interconnect layers between the interconnect layers M₀ and Mₓ₋₁ are omitted. Each of the interconnect layers M₀, . . . . Mₓ₋₁, Mₓ, Mₓ₊₁ includes an inter-metal dielectric (IMD) portion 31, and a plurality of electrically conductive elements 32 (for example, metal contacts, metal lines, and/or metal vias) formed in the IMD portion 31. Each of the electrically conductive elements 32 in each of the interconnect layers M₀ . . . . Mₓ₋₁, Mₓ, Mₓ₊₁ is connected to a corresponding one of the electrically conductive elements 32 in an adjacent one of the interconnect layers M₀ . . . . Mₓ₋₁, Mₓ, Mₓ₊₁. In some embodiments, the second semiconductor structure 40 is formed in the IMD portion 31 of the interconnect layer Mₓ. In some embodiments, the electrically conductive elements 32 may include a low resistance electrically conductive material such as copper (Cu), cobalt (Co), ruthenium (Ru), molybdenum (Mo), chromium (Cr), tungsten (W), manganese (Mn), rhodium (Rh), iridium (Ir), nickel (Ni), palladium (Pd), platinum (Pt), golden (Au), silver (Ag), aluminum (Al), osmium (Os), alloys thereof, or combinations thereof. Possible low dielectric constant (low-k) materials suitable for the IMD portion 31 are similar to those for forming the ILD layer 11, and thus the details thereof are omitted for the sake of brevity.

In some embodiments, the second semiconductor structure 40 may be a thin-film transistor (TFT), and includes a channel 41 that includes a semiconductor material, a gate dielectric layer 42 disposed below the channel 41, a gate electrode 43 disposed below the gate dielectric layer 42 such that the channel 41 is separated from the gate electrode 43 by the gate dielectric layer 42, a drain unit 51 and a source unit 52 connected to the channel 41 and spaced apart from each other, a cap layer 44 disposed on the channel 41 opposite to the gate electrode 43, a first interface layer 45 disposed between the gate dielectric layer 42 and the gate electrode 43, and a second interface layer 46 disposed between the gate dielectric layer 42 and the channel 41.

In some embodiments, as shown in FIG. 1, the gate electrode 43 is located beneath the channel 41 such that the gate electrode 43 and the channel 41 are respectively located proximate to and distal from the substrate 10. In such case, the second semiconductor structure 40 is referred to as a bottom-gate TFT, but is not limited thereto. In some other embodiments not shown herein, the second semiconductor structure 40 may be configured as a top-gate TFT, a double-gate TFT, a vertical TFT, or 3-dimensional TFT. For the top-gate TFT, the gate electrode and the channel are respectively located distal from and proximate to the substrate. The double gate TFT includes a lower gate electrode and an upper gate electrode which are respectively separated from the channel by a lower gate electric layer and an upper gate dielectric layer. The lower and upper gate electrodes are disposed at two opposite sides of the channel, and are respectively located proximate to and distal from the substrate 10. In some embodiments, the second semiconductor structure 40 may be applied to a static random-access memory (SRAM), a dynamic random-access memory (DRAM, e.g., a one-transistor/one-capacitor (1T-1C) DRAM cell, a 3-dimensional DRAM structure, a standalone DRAM structure, an embedded DRAM structure, etc.), ferroelectric memories (e.g., 1T-1C ferroelectric random-access memory (1T-1C FeRAM), 1T FeRAM, metal-ferroelectric-metal field-effect transistor-based (MFMFET-based) FeRAM, metal-ferroelectric-metal-insulator-semiconductor field-effect transistor-based (MFMISFET) FeRAM, etc.), or peripheral devices (e.g., power gates, input/output (I/O) devices, or selectors for memory cells, etc.). It is noted that the second semiconductor structure 40 is not limited to be formed in the IMD portion 31 of the interconnect layer Mₓ. In some embodiments not shown herein, the second semiconductor structure 40 may be formed in any one of the interconnect layers M₀ . . . . Mₓ₋₁, Mₓ₊₁.

In some embodiments, as shown in FIG. 1, the gate electrode 43 is disposed on the IMD portion 31 of the interconnect layer Mₓ₋₁, and is connected to one of the electrically conductive elements 32 of the interconnect layer Mₓ₋₁. In some embodiments, the gate electrode 43 includes tungsten (W), platinum (Pt), aluminum (Al), silver (Ag), copper (Cu), nickel (Ni), gold (Au), or alloys thereof. Other metallic material (e.g., metal nitride (for example, but not limited to, titanium nitride) suitable for forming the gate electrode 43 are within the contemplated scope of the present disclosure. In some embodiments, the gate electrode 43 has a thickness ranging from about 50 nm to about 10,000 nm. If the thickness of the gate electrode 43 is less than 50 nm, the conductivity is decreased. If the thickness of the gate electrode 43 is greater than 10,000 nm, the memory density is decreased.

In some embodiments, the gate dielectric layer 42 is disposed on the gate electrode 43. In other words, the gate electrode 43 is disposed below a lower surface of the gate dielectric layer 42. In some embodiments, the gate dielectric layer 42 may include silicon oxide, silicon nitride, silicon oxynitride, or a high-k dielectric material (such as hafnium oxide, hafnium tantalum oxide, zirconium oxide, zirconium aluminum oxide, hafnium aluminum oxide, hafnium silicon oxide, aluminum oxide, etc.). In some other embodiments, when the second semiconductor structure 40 is formed as a FeRAM, the gate dielectric layer 42 may include a ferroelectric material (such as hafnium zirconium oxide, barium titanate, lead titanate, lead zirconate, lithium niobate, sodium niobate, potassium niobate, potassium tantalite, bismuth scandate, bismuth ferrite, aluminum scandium nitride, or hafnium oxide doped with yttrium (Y), lanthanum (La), gadolinium (Gd), erbium (Er), titanium (Ti), zirconium (Zr), aluminum (Al), or tantalum (Ta)). Other suitable materials for the gate dielectric layer 42 are within the contemplated scope of disclosure. In some embodiments, the gate dielectric layer 42 has a thickness ranging from about 1 nm to about 1,000 nm. If the thickness of the gate dielectric layer 42 is less than 1 nm, the gate dielectric layer 42 cannot be polarized effectively. If the thickness of the gate dielectric layer 42 is greater than 1,000 nm, the operation voltage and the dynamic operation power is increased. In some embodiments, as shown in FIG. 1, the gate dielectric layer 42 has a first region 421 for forming the channel 41 thereon, two second regions 422 respectively for forming the drain unit 51 and the source unit 52 thereon, and a third region 423 for being covered by the IMD portion 31 of the interconnect layer Mₓ. The regions 421, 422, 423 are displaced from each other.

In some embodiments, the channel 41 is formed on the first region 421 of the gate dielectric layer 42. In other words, the gate dielectric layer 42 is formed below a lower surface of the channel 41. In some embodiments, the semiconductor material for forming the channel 41 includes silicon (Si), germanium (Ge), silicon germanium, silicon germanium carbide, gallium arsenic, indium phosphide, gallium phosphide, gallium nitride, gallium antimony, aluminum arsenic, indium arsenic, indium antimony, indium gallium arsenide, aluminum gallium arsenic, aluminum gallium indium phosphide, gallium indium arsenic, gallium indium phosphide, indium aluminum arsenic, aluminum indium gallium phosphide, cadmium sulfide, cadmium selenide, zinc sulfide, zinc selenide, zinc telluride, lead sulfide, lead telluride, mercury telluride, or combinations thereof. In some other embodiments, the semiconductor material for forming the channel 41 may have an n-type conductivity. That is, the channel 41 may include an n-type metal oxide semiconductor, such as indium gallium zinc oxide (IGZO), indium zinc oxide (IZO), indium gallium tin oxide (IGSnO), indium gallium tin zinc oxide (IGSnZnO), which has extra charge carriers (i.e., electrons) capable of moving in the channel 41 during operation of the second semiconductor structure 40. In such case, the second semiconductor structure 40 using the n-type metal oxide semiconductor as the channel 41 is referred to as an n-type TFT, electrons are majority carriers in the channel 41, and such channel 41 may be referred to as an n-channel. In some yet other embodiments, the semiconductor material for forming the channel 41 may have a p-type conductivity. That is, the channel 41 may include a p-type metal oxide semiconductor, such as copper oxide (Cu₂O), tin oxide (SnO), nickel oxide (NiO), K₂Sn₂O₃, Al-doped NiO (Al:NiO), V-doped NiO (V:NiO), Cu-doped NiO (Cu:NiO), Sn-doped NiO (Sn:NiO), Mg-doped NiO (Mg:NiO), Li-doped MgNiO (Li:MgNiO), RbSn₂O₃, TiSnO₃, Sn₅(PO₅)₂, Ta₂Sn₂O₆, Pb-doped CsSnI₃ (Pb:CsSnI₃), CuCrO₂, Mg-doped Cu₂O (Mg:Cu₂O), CuFeO₂, CsPbIBr₂, Cs-NiOx, bathocuproine (BCP), or phenyl-C61-butyric acid methyl ester (PCBM), which has extra charge carriers (i.e., holes) capable of moving in the channel 41 during operation of the second semiconductor structure 40. In such case, the second semiconductor structure 40 using the p-type metal oxide semiconductor as the channel 41 is referred to as a p-type TFT, holes are majority carriers in the channel 41, and such channel 41 may be referred to as a p-channel. In some embodiments, the channel 41 may have a thickness ranging from about 1 nm to about 500 nm. If the thickness of the channel 41 is less than 1 nm, the contact resistance between the channel 41 and the drain unit 51 (or the source unit 52) is increased. If the thickness of the channel 41 is greater than 500 nm, the static current leakage and the static power are increased. As shown in FIG. 16, in some embodiments, the channel 41 has a length (L1) ranging from about 3 nm to about 1,000 nm. If the length (L1) of the channel 41 is less than 3 nm, the current leakage is increased. If the length (L1) of the channel 41 is greater than 1,000 nm, the memory density and the drain current are decreased. In some embodiments, the channel 41 has a width (W1) ranging from about 100 nm to about 10,000 nm. If the width (W1) of the channel 41 is less than 100 nm, the current leakage is increased. If the width (W1) of the channel 41 is greater than 10,000 nm, the memory density and the drain current are decreased.

In some embodiments, the drain unit 51 and the source unit 52 are respectively disposed on the second regions 422 of the gate dielectric layer 42, and are respectively located at two opposite sides of the channel 41. In other words, the drain unit 51 and the source unit 52 are respectively connected to a drain-side surface 411 and a source-side surface 412 of the channel 41. In some embodiments in which the second semiconductor structure 40 is formed as a TFT, when a specified voltage (V_{GS}) is applied between the gate electrode 43 and the source unit 52 to bias the second semiconductor structure 40 to an on-state, the majority carriers (electrons in an n-channel or holes in a p-channel) may flow in a direction from the source unit 52 toward the drain unit 51, and thus an on-state drain current (Ion) may be detected at the drain unit 51. In some embodiments, the on-state drain current (Ion) may increase as the thickness of the channel 41 increases. For example, the on-state drain current (Ion) may increase from about 60 μA/μm to about 200 μA/μm as the thickness of the channel 41 increases from about 1 nm to about 100 nm. In some other embodiments, when the second semiconductor structure 40 serves as a memory device (e.g., a FeRAM), and includes the drain and source units 51, 52 having the arrangement as described above (i.e., the drain and source units 51, 52 are in direct contact with the gate dielectric layer 42), a polarizable region of the gate dielectric layer 42 can be enlarged, and a memory window of the FeRAM may be enlarged accordingly. Furthermore, when a read voltage (V_{GS}) is applied between the gate electrode 43 and the source unit 52, the majority carriers (electrons in an n-channel or holes in a p-channel) may flow in a direction from the source unit 52 toward the drain unit 51, and thus a programmed state or an erased state of the FeRAM may be determined according to the on-state drain current (Ion) detected at the drain unit 51.

As shown in FIG. 16, in some embodiments, each of the drain unit 51 and the source unit 52 has a length (L2) ranging from about 30 nm to about 10,000 nm. If the length (L2) of each of the drain unit 51 and the source unit 52 is less than 30 nm, the conductivity of each of the drain unit 51 and the source unit 52 is decreased. If the length (L2) of each of the drain unit 51 and the source unit 52 is greater than 10,000 nm, the memory density is decreased. In some embodiments, each of the drain unit 51 and the source unit 52 has a width (W2) ranging from about 100 nm to about 10,000 nm. If the width (W2) of each of the drain unit 51 and the source unit 52 is less than 100 nm, the conductivity of each of the drain unit 51 and the source unit 52 is decreased. If the width (W2) of each of the drain unit 51 and the source unit 52 is greater than 10,000 nm, the memory density is decreased.

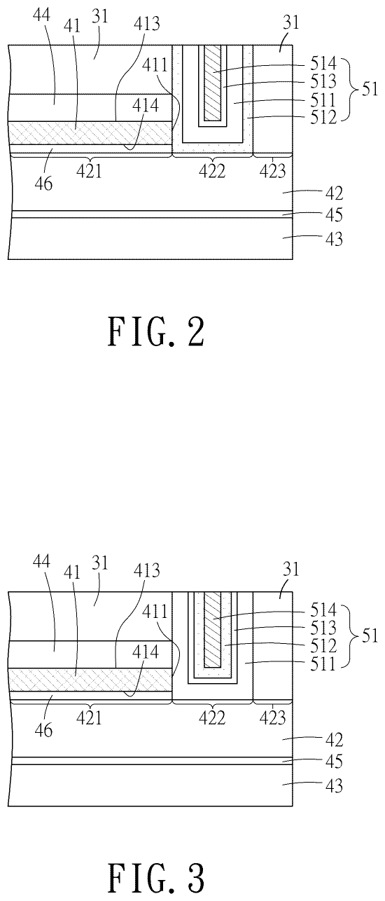

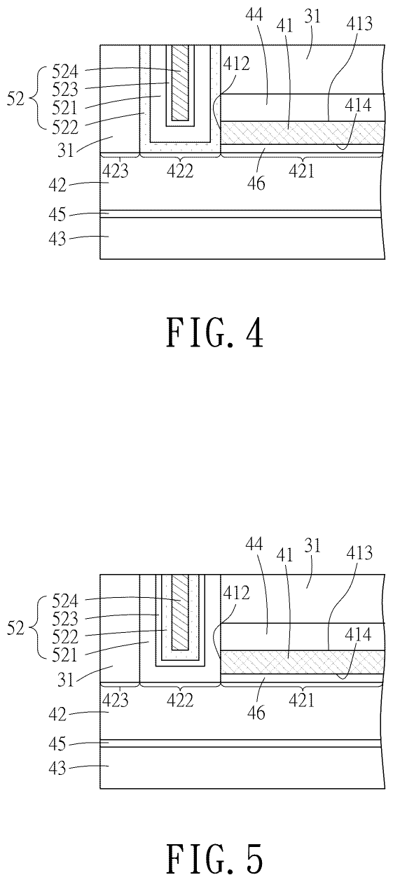

As shown in FIG. 1, the drain unit 51 includes a drain-side conductive metal oxide layer 511, a drain-side tunnel layer 512, a drain-side diffusion blocking layer 513, and a drain electrode 514. The drain-side tunnel layer 512 is disposed between the channel 41 and the drain electrode 514 to adjust a first barrier height between the drain electrode 514 and the channel 41. In some embodiments, the drain-side conductive metal oxide layer 511 is connected to the drain-side surface 411 of the channel 41, the drain-side tunnel layer 512 is disposed on the drain-side conductive metal oxide layer 511, the drain-side diffusion blocking layer 513 is disposed on the drain-side tunnel layer 512, and the drain electrode 514 is disposed on the drain-side diffusion blocking layer 513 (as shown in FIG. 1). In some other embodiments, the drain-side tunnel layer 512 may be disposed between the channel 41 and the drain-side conductive metal oxide layer 511 (as shown in FIG. 2). In some other embodiments, the drain-side tunnel layer 512 may be disposed between the drain-side diffusion blocking layer 513 and the drain electrode 514 (as shown in FIG. 3). The source unit 52 includes a source-side conductive metal oxide layer 521, a source-side tunnel layer 522, a source-side diffusion blocking layer 523, and a source electrode 524. The source-side tunnel layer 522 is disposed between the channel 41 and the source electrode 524 to adjust a second barrier height between the source electrode 524 and the channel 41. In some embodiments, the source-side conductive metal oxide layer 521 is connected to the second-side surface 412 of the channel 41, the source-side tunnel layer 522 is disposed on the source-side conductive metal oxide layer 521, the source-side diffusion blocking layer 523 is disposed on the source-side tunnel layer 522, and the source electrode 524 is disposed on the source-side diffusion blocking layer 523 (as shown in FIG. 1). In some other embodiments, the source-side tunnel layer 522 may be disposed between the channel 41 and the source-side conductive metal oxide layer 521 (as shown in FIG. 4). In some other embodiments, the source-side tunnel layer 522 may be disposed between the source-side diffusion blocking layer 523 and the source electrode 524 (as shown in FIG. 5).

In some embodiments, the drain-side conductive metal oxide layer 511 (or the source-side conductive metal oxide layer 521) is used to reduce a contact resistance between the channel 41 and the drain electrode 514 (or the source electrode 524). As such, each of the drain-side and source-side conductive metal oxide layers 511, 521 has an conductivity which is lower than that of each of the drain and source electrodes 514, 524, and which is higher than that of the channel 41. In some embodiments, each of the drain-side and source-side conductive metal oxide layers 511, 521 may be independently made of indium gallium zinc oxide (IGZO), indium gallium oxide (IGO), indium zinc oxide (IZO), indium oxide, zinc oxide, tin oxide, zinc tin oxide (ZnSnO, ZTO), gallium zinc oxide (GZO), indium tin oxide (InSnO, ITO), fluorine-doped tin oxide (FTO), or other high conductive metal oxides having high donor (i.e., electrons) density. It is noted that, in comparison with the n-type metal oxide semiconductor for forming the channel 41 (such as the examples described in the previous paragraph), the metal oxides for forming the drain-side and source-side conductive metal oxide layers 511, 521 has a relatively high donor (i.e., electrons) density. In other words, the conductivity of the metal oxides for forming the drain-side and source-side conductive metal oxide layers 511, 521 is greater than the conductivity of the metal oxide semiconductor for forming the channel 41. In some embodiments, each of the drain-side and source-side conductive metal oxide layers 511, 521 may have a thickness ranging from about 1 nm to about 5 nm. If the thickness of each of the drain-side and source-side conductive metal oxide layers 511, 521 is less than 1 nm, the contact resistance is increased. If the thickness of each of the drain-side and source-side conductive metal oxide layers 511, 521 is greater than 5 nm, the memory density is decreased. The thicknesses of the drain-side and source-side conductive metal oxide layers 511, 521 may be the same as or different from each other.

As described above, the drain-side tunnel layer 512 is provided to adjust the first barrier height between the drain electrode 514 and the channel 41, and the source-side tunnel layer 522 is provided to adjust the second barrier height between the source electrode 524 and the channel 41. The first barrier height and the second barrier height may vary depending on the thicknesses of the drain-side tunnel layer 512 and the source-side tunnel layer 522, and thus a threshold voltage of the second semiconductor structure 40 may be adjusted, so as to permit the second semiconductor structure 40 to be used in application with low power consumption (such as an artificial intelligence (AI) memory device). In some embodiments in which the second semiconductor structure 40 serves as a memory device, the threshold voltage of the second semiconductor structure 40 may be an initial threshold voltage (i.e., the threshold voltage when the second semiconductor structure 40 is in an initial state, Vₜ₍ᵢₙᵢₜᵢₐₗ₎), a programmed threshold voltage (i.e., the threshold voltage when the second semiconductor structure 40 is in a programmed state, V_{t(PRG)}), or an erased threshold voltage (i.e., the threshold voltage when the second semiconductor structure 40 is in an erased state, V_{t(ERS)}).

In some embodiments in which the second semiconductor structure 40 is an n-type TFT and the channel 41 is an n-channel (i.e., the semiconductor material for forming the channel 41 has an n-type conductivity), with the provision of the drain-side and source-side tunnel layers 512, 522, the threshold voltage of the second semiconductor structure 40 serving as the n-type TFT can be shifted from a relatively negative value (without the drain-side and source-side tunnel layers 512, 522) to a relatively positive value (a negative value with a smaller absolute value or a positive value). In some embodiments, the threshold voltage of the second semiconductor structure 40 may be adjusted to a range from 0 eV to about 2 eV. As such, when no voltage is applied to the second semiconductor structure 40 or the second semiconductor structure 40 is in a standby mode, a static power dissipation, which results from leakage current in the second semiconductor structure 40, may be suppressed. The first barrier height formed between the drain electrode 514 and the channel 41 may be referred to as a first electron barrier height. The second barrier height formed between the source electrode 524 and the channel 41 and may be referred to as a second electron barrier height. In some embodiments, the first electron barrier height is greater than the second electron barrier height, and thus degradation of an on-state drain current may be prevented or alleviated (i.e., the on-state drain current (Ion) of the second semiconductor structure 40 is relatively large).

In some other embodiments in which the second semiconductor structure 40 is a p-type TFT and the channel 41 is a p-channel, with the provision of the drain-side and source-side tunnel layers 512, 522, the threshold voltage of the second semiconductor structure 40 serving as the p-type TFT can be shifted from a relatively large positive value (without the drain-side and source-side tunnel layers 512, 522) toward a relative small positive value or a negative value, thereby suppressing the static power dissipation of the second semiconductor structure 40. The first barrier height formed between the drain electrode 514 and the channel 41 may be referred to as a first hole barrier height. The second barrier height formed between the source electrode 524 and the channel 41 may be referred to as a second hole barrier height. In some embodiments, the first hole barrier height is greater than the second hole barrier height, and thus degradation of an on-state drain current may be prevented or alleviated (i.e., the on-state drain current (Ion) of the second semiconductor structure 40 is relatively large).

In some embodiments, the drain-side tunnel layer 512 includes a drain tunnel material, and the source-side tunnel layer 521 includes a source tunnel material. Each of the drain tunnel material and the source tunnel material may be independently selected from titanium oxide, hafnium oxide, zirconium oxide, gallium oxide, aluminum oxide, silicon oxide, or combinations thereof.

In some embodiments, the drain-side tunnel layer 512 has a first thickness ranging from about 0.5 nm to about 5 nm. In some embodiments, the source-side tunnel layer 522 has a second thickness ranging from about 0.5 nm to about 5 nm. The greater the thickness of each of the drain-side and source side tunnel layers 512, 522 is, the greater the shift of the threshold voltage of the second semiconductor structure 40 is. If the first thickness or the second thickness is less than 0.5 nm, the threshold voltage of the second semiconductor structure 40 cannot be tuned effectively. If the first thickness or the second thickness is greater than 5 nm, the resistance is increased.

In some embodiments, each of the drain-side and source-side diffusion blocking layers 513, 523 is provided for preventing metal atoms in a corresponding one of the drain and source electrodes 514, 524 from diffusing into the IMD portion 31 of the interconnect layer Mₓ, so that undesired current leakage may be eliminated. In some embodiments, each of the drain-side and source-side diffusion blocking layers 513, 523 may include titanium nitride (TiN), tungsten carbon nitride (WCN), tungsten nitride (WN), tantalum nitride (TaN), tantalum (Ta), cobalt (Co), or combinations thereof. Other materials suitable for forming the drain-side and source-side diffusion blocking layers 513, 523 are also within the contemplated scope of the present disclosure. In some embodiments, each of the drain-side and source-side diffusion blocking layers 513, 523 may have a thickness ranging from about 0.5 nm to about 5 nm. If the thickness of the drain-side diffusion blocking layer 513 or the source-side diffusion blocking layers 523 is less than 0.5 nm, the metal atoms in a corresponding one of the drain and source electrodes 514, 524 cannot be prevented from diffusing into the IMD portion 31 of the interconnect layer Mₓ. If the thickness of the drain-side diffusion blocking layer 513 or the source-side diffusion blocking layers 523 is greater than 5 nm, the contact resistance is increased.

In some embodiments, the drain electrode 514 includes a first electrically conductive material, and the source electrode 524 includes a second electrically conductive material. The first electrically conductive material may be the same as or different from the second electrically conductive material. In some embodiments in which the channel 41 is the n-channel, each of the first and second electrically conductive materials has a metal work function value of greater than about 3 eV, and may include, for example, but not limited to, platinum (Pt), ruthenium (Ru), palladium (Pd), tungsten (W), gold (Au), aluminum (Al), cobalt (Co), copper (Cu), titanium (Ti), tantalum (Ta), zirconium (Zr), hafnium (Hf), or alloys thereof. Other metallic materials suitable for forming the drain and source electrodes 514, 524 are within the contemplated scope of the present disclosure. In some embodiments in which the channel 41 is the p-channel, each of the first and second electrically conductive materials has a metal work function value of less than about 4 eV, and may include, for example, but not limited to, hafnium (Hf), thallium (TI), arsenic (As), magnesium (Mg), uranium (U), lanthanum (La), scandium (Sc), thorium (Th), lutetium (Lu), neodymium (Nd), gadolinium (Gd), yttrium (Y), terbium (Tb), lithium (Li), cerium (Ce), calcium (Ca), sodium (Na), samarium (Sm), barium (Ba), strontium (Sr), europium (Eu), potassium (K), rubidium (Rb), caesium (Cs), or alloys thereof. Other metallic materials suitable for forming the drain and source electrodes 514, 524 are within the contemplated scope of the present disclosure. The drain and source electrodes 514, 524 made of the first and second electrically conductive materials having a large metal work function value (for example, greater than about 3 eV) can prevent contaminants, such as hydrogen gas, that are generated during fabrication of the semiconductor device or that naturally exist in the environmental atmosphere, from diffusing into the channel 41 therethrough. In some embodiments, the drain electrode 514 has a first thickness ranging from about 1 nm to about 500 nm. In some embodiments, the source electrode 524 has a second thickness ranging from about 1 nm to about 500 nm. If the first thickness (or the second thickness) is less than 1 nm, the resistance of the drain electrode 514 (or the source electrode 524) is increased. If the first thickness or the second thickness is greater than 500 Å, the memory density is decreased.

In some embodiments, each of the drain and source electrodes 514, 524 has an upper surface distal from the substrate 10, a lower surface proximate to the substrate 10, and an interconnecting surface connecting the upper surface and the lower surface. A drain-side film stack includes the drain-side conductive metal oxide layer 511, the drain-side tunnel layer 512, and the drain-side diffusion blocking layer 513. In some embodiments, as shown in FIG. 1, the drain-side tunnel layer 512 is stacked on the drain-side conductive metal oxide layer 511, and the drain-side diffusion blocking layer 513 is stacked on the drain-side tunnel layer 512. In some other embodiments, the drain-side conductive metal oxide layer 511 is stacked on the drain-side tunnel layer 512, and the drain-side diffusion blocking layer 513 is stacked on the drain-side conductive metal oxide layer 511 (as shown in FIG. 2). In some other embodiments, the drain-side diffusion blocking layer 513 is stacked on the drain-side conductive metal oxide layer 511, and the drain-side tunnel layer 512 is stacked on the drain-side diffusion blocking layer 513 (as shown in FIG. 3). A source-side film stack includes the source-side conductive metal oxide layer 521, the source-side tunnel layer 522, and the source-side diffusion blocking layer 523. In some embodiments, as shown in FIG. 1, the source-side tunnel layer 522 is stacked on the source-side conductive metal oxide layer 521, and the source-side diffusion blocking layer 523 is stacked on the source-side tunnel layer 522. In some other embodiments, the source-side conductive metal oxide layer 521 is stacked on the source-side tunnel layer 522, and the source-side diffusion blocking layer 523 is stacked on the source-side conductive metal oxide layer 521 (as shown in FIG. 4). In some other embodiments, the source-side diffusion blocking layer 523 is stacked on the source-side conductive metal oxide layer 521, and the source-side tunnel layer 522 is stacked on the source-side diffusion blocking layer 523 (as shown in FIG. 5). In some embodiments, as shown in FIG. 1, the drain-side film stack and the source-side film stack are respectively formed around the drain electrode 514 and the source electrode 524 such that the lower surface and the interconnecting surface of each of the drain and source electrodes 514, 524 are covered by a respective one of the drain-side and source-side film stacks. In such case, not only the channel 41 is separated from each of the drain and source electrodes 514, 524 by a respective one of the drain-side and source-side film stacks, but also the gate dielectric layer 42 is separated from each of the drain and source electrodes 514, 524 by a respective one of the drain-side and source-side film stacks.

The cap layer 44 is formed on an upper surface 413 of the channel 41 opposite to a lower surface 414 of the channel 41. Each of the upper surface 413 and the lower surface 414 interconnects the drain-side surface 411 and the source-side surface 412. The upper surface 413 and the lower surface 414 are respectively located distal from and proximate to the gate electrode 43. The cap layer 44 is configure to prevent contaminants, such as hydrogen gas, from diffusing into the channel 41 and damaging the channel 41. In some embodiments, the cap layer 44 includes, for example, but not limited to, aluminum oxide, silicon oxide, or a combination thereof. In some embodiments, the cap layer 44 has a thickness ranging from about 1 nm to about 500 nm. If the thickness of the cap layer 44 is less than 1 nm, the contaminants, such as hydrogen gas, cannot be effectively prevented from diffusing into the channel 41. If the thickness of the cap layer 44 is greater than 500 nm, the memory density is decreased. The cap layer 44 may be configured as a single-layered structure, e.g., a layer of aluminum oxide or silicon oxide, or a dual-layered structure, which includes a sub-layer of silicon oxide and a sub-layer of aluminum oxide.

The first interface layer 45 is disposed between the gate dielectric layer 42 and the gate electrode 43, and the second interface layer 46 is disposed between the gate dielectric layer 42 and the channel 41. Each of the first interface layer 45 and the second interface layer 46 is made of a high-k dielectric material, and is used for reducing an electric field and improving the endurance of the second semiconductor structure 40. The first interface layer 45 is used to reduce the electric field between the gate electrode 43 and the gate dielectric layer 42. The second interface layer 46 is used to reduce the electric field between the channel 41 and the gate dielectric layer 42. In some embodiments, the high-k dielectric material includes, for example, but not limited to, titanium oxide, hafnium oxide, zirconium oxide, niobium oxide, cerium oxide, or combinations thereof. The high-k dielectric material for forming the first interface layer 45 may be the same as or different from that for forming the second interface layer 46. In some embodiments, each of the first interface layer 45 and the second interface layer 46 may have a thickness ranging from about 0.1 nm to about 20 nm.

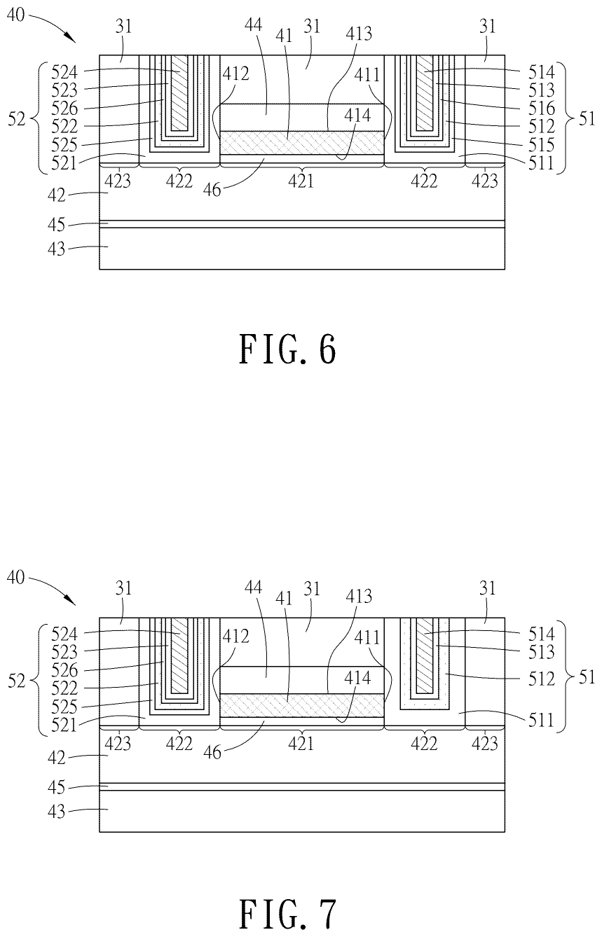

FIG. 6 is a schematic sectional view illustrating the second semiconductor structure 40 in accordance with some other embodiments. The second semiconductor structure 40 shown in FIG. 6 has a structure similar to the second semiconductor structure 40 shown in FIG. 1, except that the drain unit 51 further includes a first drain-side interface layer 515 and a second drain-side interface layer 516, and that the source unit 52 further includes a first source-side interface layer 525 and a second source-side interface layer 526. The first drain-side interface layer 515 is disposed between the drain-side conductive metal oxide layer 511 and the drain-side tunnel layer 512 so as to reduce an electric field between the drain-side conductive metal oxide layer 511 and the drain-side tunnel layer 512. The second drain-side interface layer 516 is disposed between the drain-side tunnel layer 512 and the drain-side diffusion blocking layer 513 so as to reduce an electric field between the drain-side tunnel layer 512 and the drain-side diffusion blocking layer 513. The first source-side interface layer 525 is disposed between the source-side conductive metal oxide layer 521 and the source-side tunnel layer 522 so as to reduce an electric field between the source-side conductive metal oxide layer 521 and the source-side tunnel layer 522. The second source-side interface layer 526 is disposed between the source-side tunnel layer 522 and the source-side diffusion blocking layer 523 so as to reduce an electric field between the source-side tunnel layer 522 and the source-side diffusion blocking layer 523. Each of the first drain-side interface layer 515, the second drain-side interface layer 516, the first source-side interface layer 525 and the second source-side interface layer 526 may be the same as or similar to the first interface layer 45 or the second interface layer 46, and thus the details thereof are omitted for the sake of brevity.

FIG. 7 is a schematic sectional view illustrating the second semiconductor structure 40 in accordance with some other embodiments. The second semiconductor structure 40 shown in FIG. 7 has a structure similar to the second semiconductor structure 40 shown in FIG. 1 or FIG. 6, except that one of the drain unit 51 and the source unit 52 (for example, the drain unit 51 as shown in FIG. 7) has a structure which is the same as that of the drain unit 51 or the source unit 52 of the second semiconductor structure 40 shown in FIG. 1, and that the other of the drain unit 51 and the source unit 52 (for example, the source unit 52 as shown in FIG. 7) has a structure which is the same as that of the drain unit 51 or the source unit 52 of the second semiconductor structure 40 shown in FIG. 6.

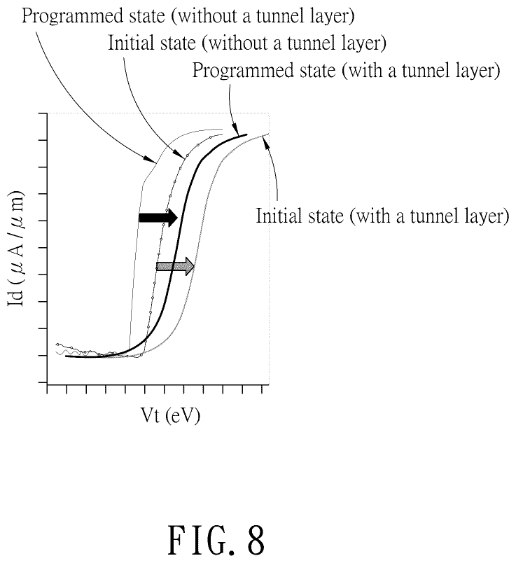

Referring to FIG. 8, as described above, in some embodiments in which the second semiconductor structure 40 is the n-type TFT and the channel 41 is the n-channel (i.e., the semiconductor material for forming the channel 41 has the n-type conductivity), with the provision of the drain-side and source-side tunnel layers 512, 522, the threshold voltage of the second semiconductor structure 40 in the initial state or the programmed state can be shifted from a relatively negative value (which is obtained from a semiconductor structure without the drain-side and source-side tunnel layers 512, 522) to a relatively positive value (a negative value with a smaller absolute value or a positive value). As such, when no voltage is applied to the second semiconductor structure 40 or the second semiconductor structure 40 is in a standby mode, a static power dissipation, which results from leakage current in the second semiconductor structure 40, may be suppressed.

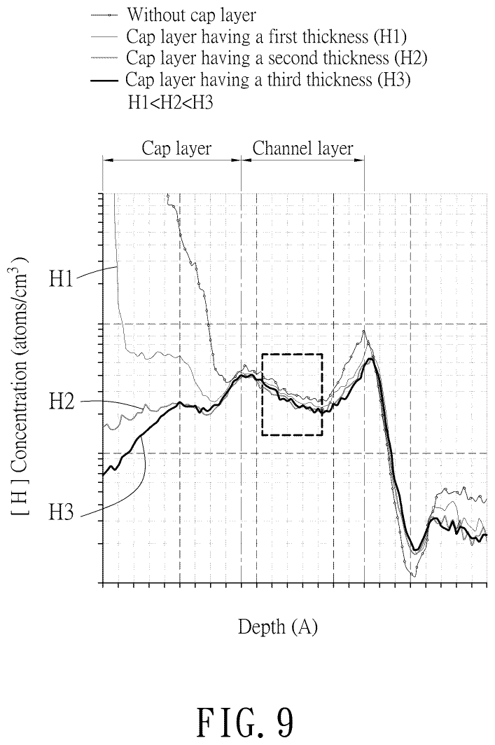

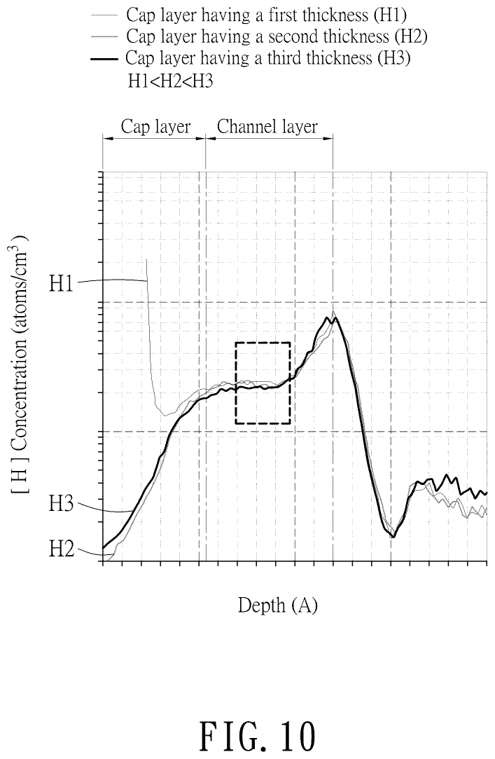

Two groups of samples are subjected to a secondary ion mass spectrometry test. FIG. 9 is a diagram showing distribution of hydrogen concentration in the first group of samples, in which one of the samples is formed without the cap layer 44 (see FIG. 1) and three of the samples are respectively formed with the three cap layers 44 having different thicknesses. FIG. 10 is a diagram showing distribution of hydrogen distribution in the second group of samples, in which the samples are respectively formed with the cap layers 44 having different thicknesses.

Referring to FIG. 9, for the first group of samples, it is noted that at the channel region (see the region enclosed in dotted line), the hydrogen concentration of each of the three samples having the cap layer 44 is lower than the hydrogen concentration of the sample without the cap layer 44, indicating that the cap layer 44 is effective in hindering contaminants, such as hydrogen gas, from diffusing into the channel 41. Thus, the cap layer 44 is effective in lowering the hydrogen concentration of the channel 41.

Referring to FIG. 10, for the second group of samples, which respectively have the cap layers 44 with different thicknesses, it is noted that at the channel region (see the region enclosed in dotted line), the hydrogen concentration of the sample having the cap layer 44 with a relatively large thickness is lower than the hydrogen concentration of the sample having the cap layer 44 with a relatively small thickness, indicating that compared to the cap layer 44 having the relatively small thickness, the cap layer 44 having the relatively large thickness is more effective in hindering contaminants, such as hydrogen gas, from diffusing into the channel 41. Thus, the cap layer having the relatively large thickness is more effective in lowering the hydrogen concentration of the channel 41.

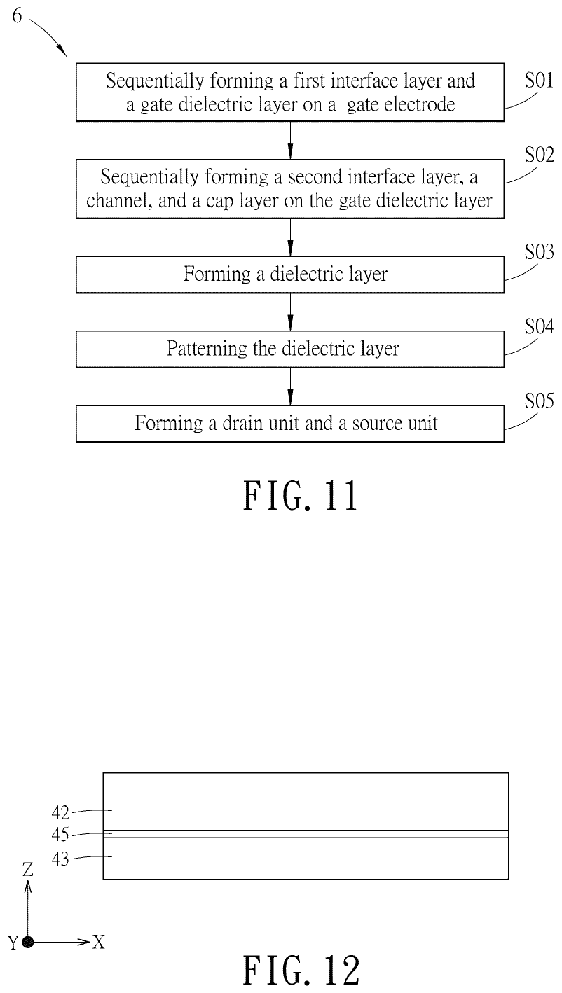

FIG. 11 is a flow diagram illustrating a method 6 for manufacturing the second semiconductor structure 40 (e.g., the second semiconductor structure 40 shown in FIG. 1, 6 or 7) in accordance with some embodiments. The method 6 may include steps S01 to S05. FIGS. 12 to 19 illustrate schematic views of intermediate stages of the method 6 in accordance with some embodiments. Similar numerals from the above-mentioned embodiments have been used where appropriate, with some construction differences being indicated with different numerals. In some other embodiments, the method 6 may be used for manufacturing a plurality of the second semiconductor structures 40 simultaneously, and the number of the second semiconductor structures 40 may vary according to practical requirements.

Referring to FIG. 11 and the example illustrated in FIG. 12, the method 6 begins at step S01, where the first interface layer 45 and the gate dielectric layer 42 are formed sequentially on the gate electrode 43 by atomic layer deposition (ALD), physical vapor deposition (PVD), chemical vapor deposition process (CVD), or other suitable deposition techniques. In some embodiments, a patterning process, which may include a photolithography process and an etching process following the photolithography process, may be performed so that each of the gate electrode 43, the first interface layer 45 and the gate dielectric layer 42 may have a desired dimension in an X direction parallel to the substrate 10 (see FIG. 1) or in a Y direction that is parallel to the substrate 10 and that is transverse to the X direction.

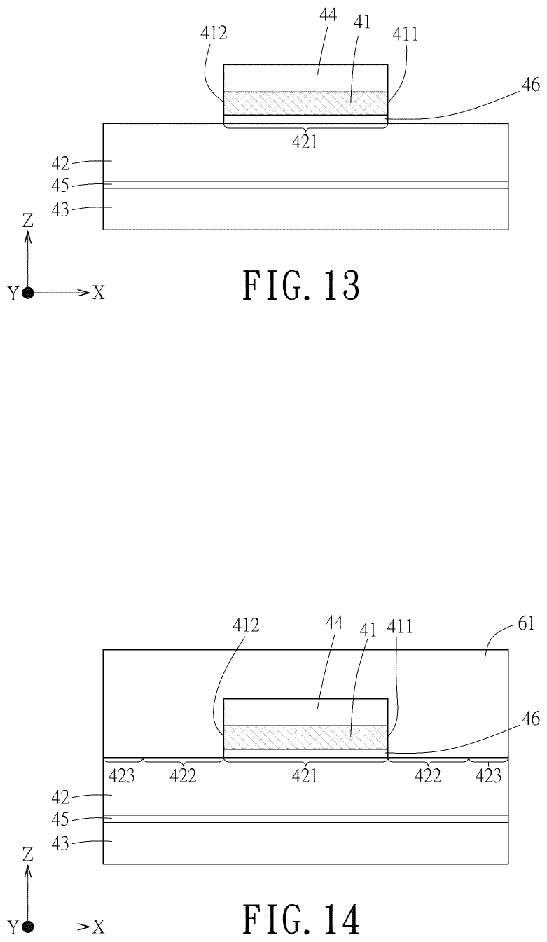

Referring to FIG. 11 and the example illustrated in FIG. 13, the method 6 proceeds to step S02, where the second interface layer 46, the channel 41 and the cap layer 44 are sequentially formed on the first region 421 of the gate dielectric layer 42 by a suitable deposition process (such as the examples described in step S01) and a patterning process which may include a photolithography process and an etching process following the photolithography process.

Referring to FIG. 11 and the example illustrated in FIG. 14, the method 6 proceeds to step S03, where a dielectric layer 61 for forming the IMD portion 31 of the interconnect layer Mₓ (see FIG. 1, 6 or 7) is formed on the structure obtained after step S02 (for example, the structure shown in FIG. 13) using a suitable deposition process (such as the examples described in step S01), followed by a planarization process, such as chemical mechanical polishing, to obtain a planar upper surface of the dielectric layer 61.

As shown in FIG. 14, in some embodiments, the dielectric layer 61 is formed on a stack of the second interface layer 46, the channel 41 and the cap layer 44, and extends to cover the second and third regions 422, 423 of the gate dielectric layer 42 opposite to the gate electrode 43.

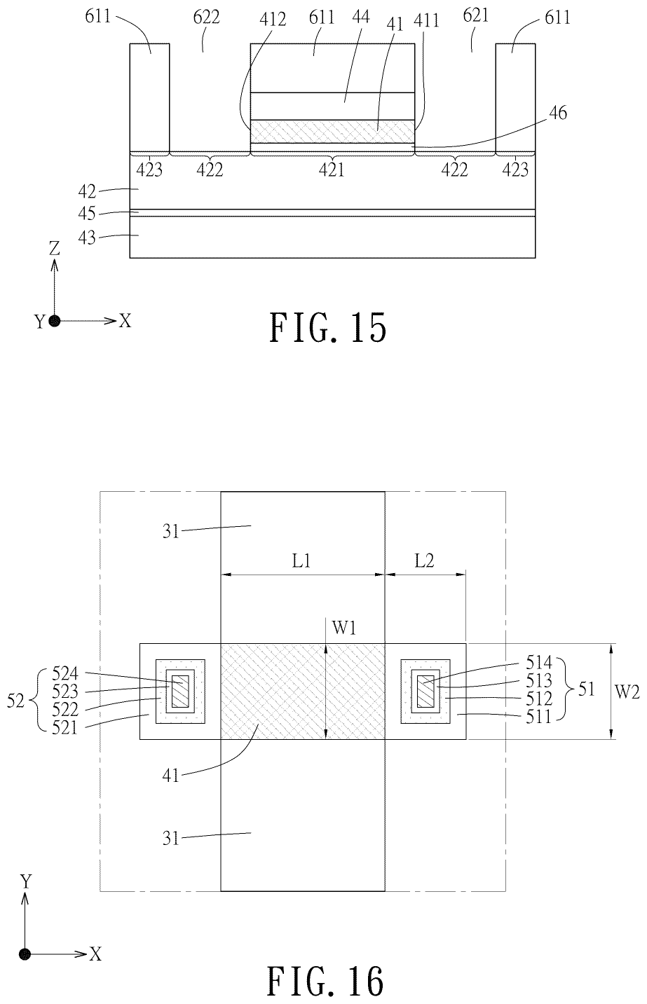

Referring to FIG. 11 and the example illustrated in FIG. 15, the method 6 proceeds to step S04, where the dielectric layer 61 (see FIG. 14) is patterned to form two openings 621, 622 spaced apart from each other. Step S04 is performed by, for example, a photolithography process and an etching process following the photolithography process. In addition, the two second regions 422 of the gate dielectric layer 42 are respectively exposed from the two openings 621, 622. The two openings 621, 622 are respectively for forming the drain and source units 51, 52 (see FIG. 1, 6 or 7) therein.

In some embodiments, as shown in FIG. 15, two opposite side surfaces of each of the second interface layer 46, the channel 41 and the cap layer 44 are respectively exposed from the two openings 621, 622. That is, the drain-side surface 411 and the source-side surface 412 of the channel 41 are respectively exposed from the two openings 621, 622. After step S04, the patterned dielectric layer is denoted by the numeral 611.

Referring to FIG. 11 and the example illustrated in FIGS. 1, 6, 7, and 16 to 19, the method 6 proceeds to step S05, where the drain unit 51 is formed in the opening 621 (see FIG. 15) and the source unit 52 is formed in the opening 622, thereby obtaining the semiconductor structure 40 shown in FIG. 1, 6 or 7. In some embodiments in which the drain and source units 51, 52 have the same film stacking, as shown in FIG. 1 or 6, the drain and source units 51, 52 may be formed at the same time, while in some other embodiments in which the drain and source units 51, 52 have different film stacking, as shown in FIG. 7, the drain and source units 51, 52 may be separately formed.

Specifically, in some embodiments, in the process for forming the drain and source units 51, 52 shown in FIG. 1, step S05 may include sequentially depositing materials respectively for forming the drain-side and source-side conductive metal oxide layers 511, 521, the drain-side and source-side tunnel layers 512, 522, the drain-side and source-side diffusion blocking layers 513, 523, and the drain and source electrodes 514, 524 along an inner surface of each of the openings 621, 622 over the patterned dielectric layer 611 to fill the openings 621, 622 (see FIG. 15) by suitable deposition processes, followed by performing a planarization process, such as chemical mechanical polishing, for a period of time until the patterned dielectric layer 611 is exposed. Thereafter, the patterned dielectric layer 611 is formed into the IMD portion 31 of the interconnect layer Mₓ.

In some embodiments, in the process for forming the drain and source units 51, 52 shown in FIG. 6, step S05 may include sequentially depositing materials respectively for forming the drain-side and source-side conductive metal oxide layers 511, 521, the first drain-side and source-side interface layers 515, 525, the drain-side and source-side tunnel layers 512, 522, the second drain-side and source-side interface layers 516, 526, the drain-side and source-side diffusion blocking layers 513, 523, and the drain and source electrodes 514, 524 along an inner surface of each of the openings 621, 622 over the patterned dielectric layer 611 to fill the openings 621, 622 (see FIG. 15) by suitable deposition processes, followed by performing a planarization process, such as chemical mechanical polishing, for a period of time until the patterned dielectric layer 611 is exposed. Thereafter, the patterned dielectric layer 611 is formed into the IMD portion 31 of the interconnect layer Mₓ.

In some other embodiments, in the process for forming the drain and source units 51, 52 shown in FIG. 7, step S05 may include sub-steps shown in FIGS. 17 to 19 and 7.

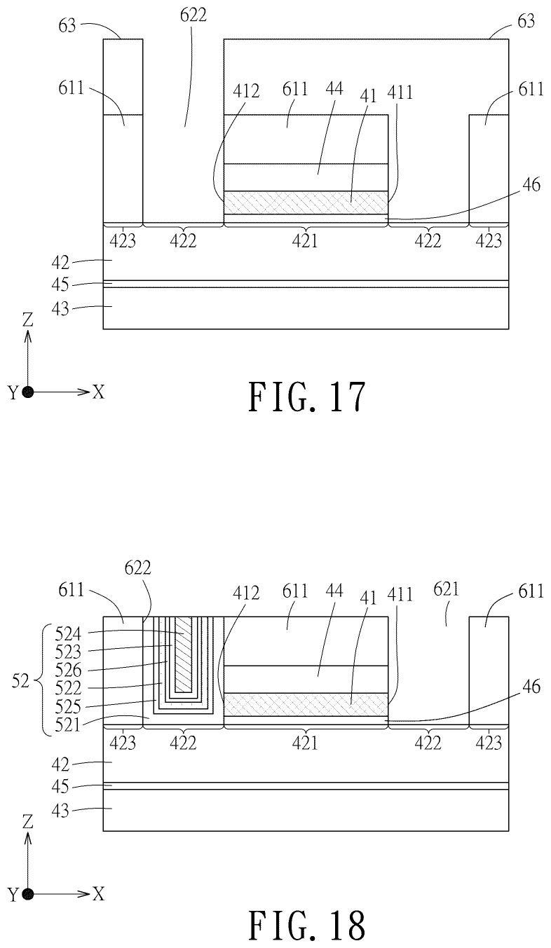

In the sub-step shown in FIG. 17, a first masking layer 63 is partially formed on the structure obtained after step S04 such that the opening 621 (see FIG. 15) is covered by the first masking layer 63 and the opening 622 is exposed from the first masking layer 63. In some embodiments, the first masking layer 63 may include an oxide, a nitride, a carbide, an oxynitride, an oxycarbide, a carbonitride, an oxycarbonitride, or combinations thereof. For example, the first masking layer 63 may be made of silicon oxide, aluminum oxide, hafnium oxide, zirconium oxide, silicon nitride, aluminum nitride, titanium nitride, silicon carbide, silicon oxycarbide, silicon oxynitride, silicon carbonitride, silicon oxycarbonitride, or combinations thereof. Other materials suitable for forming the first masking layer 63 are within the contemplated scope of the present disclosure.

In the sub-step shown in FIG. 18, the source unit 52 (see also FIG. 7) is formed after the first masking layer 63 is formed. In some embodiments, formation of the source unit 52 may include sequentially depositing materials respectively for forming the source-side conductive metal oxide layer 521, the first source-side interface layer 525, the source-side tunnel layer 522, the second source-side interface layer 526, the source-side diffusion blocking layer 523, and the source electrode 524 along the inner surface of the opening 622 (see FIG. 17) to fill the opening 622 (see FIG. 17) by suitable deposition processes; performing a planarization process, such as chemical mechanical polishing, for a period of time until the patterned dielectric layer 611 is exposed; and performing an etching process (e.g., a dry etching and/or a wet etching) to remove the first masking layer 63 (see FIG. 17).

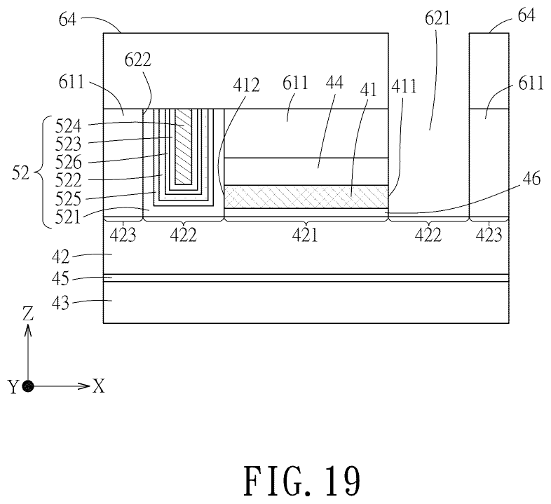

In the sub-step shown in FIG. 19, after forming the source unit 52, a second masking layer 64 is partially formed on the structure shown in FIG. 18 such that the source unit 52 is covered by the second masking layer 64 and the opening 621 is exposed from the second masking layer 64. In some embodiments, possible materials suitable for forming the second masking layer 64 are similar to those for forming the first masking layer 63, and thus the details thereof are omitted for the sake of brevity. Other materials suitable for forming the second masking layer 64 are within the contemplated scope of the present disclosure.

In the sub-step shown in FIG. 7, the drain unit 51 (see also FIG. 7) is formed after the second masking layer 64 is formed. In some embodiments, formation of the drain unit 51 may include sequentially depositing materials respectively for forming the drain-side conductive metal oxide layer 511, the drain-side tunnel layer 512, the drain-side diffusion blocking layer 513, and the drain electrode 514 along the inner surface of the opening 621 (see FIG. 19) to fill the opening 621 (see FIG. 19) by suitable deposition processes, followed by performing a planarization process, such as chemical mechanical polishing, for a period of time until the patterned dielectric layer 611 is exposed. After the planarization process, the patterned dielectric layer 611 is formed into the IMD portion 31 of the interconnect layer Mₓ. In some embodiments exemplified by FIGS. 7 and 17 to 19, the drain unit 51 is formed after formation of the source unit 52; while in some other embodiments, the drain unit 51 is formed before formation of the source unit 52.

In some embodiments, some steps in the method 6 may be modified, replaced, or eliminated without departure from the spirit and scope of the present disclosure.

In a semiconductor structure of the present disclosure, a tunnel layer is disposed between a channel and a drain electrode (or a source electrode) to adjust a barrier height between the channel and the drain electrode (or the source electrode). Therefore, a threshold voltage of the semiconductor structure may be adjusted. For example, the threshold voltage (e.g., Vₜ, or Vₜ₍ᵢₙᵢₜᵢₐₗ₎, V_{t(PRG)}, V_{t(ERS)}, etc.) of the semiconductor structure serving as an n-type TFT may be shifted to a relatively positive value, and the threshold voltage of the semiconductor structure serving as a p-type TFT may be shifted to a relatively negative value. Accordingly, current leakage may be suppressed and degradation of an on-state drain current (Ion) may be alleviated. In addition, a cap layer is disposed on the channel to prevent contaminants, such as hydrogen gas, from diffusing into the channel and damaging the channel. Moreover, each of the drain and source electrodes is made of an electrically conductive material having a large metal work function value to prevent contaminants, such as hydrogen gas, from diffusing into the channel therethrough. Furthermore, an interface layer made of a high-k dielectric material is included in the semiconductor structure of the present disclosure to reduce an electric field and to improve the endurance of the semiconductor structure.

In accordance with some embodiments of the present disclosure, a semiconductor structure includes a gate electrode, a gate dielectric layer disposed on the gate electrode, a channel disposed on the gate dielectric layer opposite to the gate electrode, and a drain unit and a source unit connected to the channel and spaced apart from each other by the channel. At least one of the drain unit and the source unit includes an electrode, and a tunnel layer disposed between the electrode and the channel so as to adjust a barrier height between the electrode and the channel.

In accordance with some embodiments of the present disclosure, the tunnel layer includes titanium oxide, hafnium oxide, zirconium oxide, gallium oxide, aluminum oxide, silicon oxide, or combinations thereof.

In accordance with some embodiments of the present disclosure, the at least one of the drain unit and the source unit further includes a conductive metal oxide layer disposed between the channel and the tunnel layer, and a diffusion blocking layer disposed between the tunnel layer and the electrode.

In accordance with some embodiments of the present disclosure, the at least one of the drain unit and the source unit further includes a conductive metal oxide layer disposed on the tunnel layer opposite to the channel, and a diffusion blocking layer disposed between the conductive metal oxide layer and the electrode.

In accordance with some embodiments of the present disclosure, the at least one of the drain unit and the source unit further includes a conductive metal oxide layer connected to the channel layer, and a diffusion blocking layer disposed between the conductive metal oxide layer and the tunnel layer.

In accordance with some embodiments of the present disclosure, the at least one of the drain unit and the source unit further includes a first interface layer disposed between the conductive metal oxide layer and the tunnel layer.

In accordance with some embodiments of the present disclosure, the at least one of the drain unit and the source unit further includes a second interface layer disposed between the tunnel layer and the diffusion blocking layer.

In accordance with some embodiments of the present disclosure, a semiconductor structure includes a gate electrode, a gate dielectric layer disposed on the gate electrode, a channel disposed on the gate dielectric layer opposite to the gate electrode, a cap layer disposed on the channel to prevent a contaminant from diffusing into the channel, and a drain unit and a source unit connected to the channel and spaced apart from each other by the channel. At least one of the drain unit and the source unit includes an electrode, and a tunnel layer disposed between the electrode and the channel so as to adjust a barrier height between the electrode and the channel.

In accordance with some embodiments of the present disclosure, the semiconductor structure further includes a first interface layer disposed between the gate electrode and the gate dielectric layer.

In accordance with some embodiments of the present disclosure, the semiconductor structure further includes a second interface layer disposed between the channel and the gate dielectric layer.

In accordance with some embodiments of the present disclosure, the channel is a channel having an n-type conductivity, and the electrode has a metal work function value of greater than about 3 eV.

In accordance with some embodiments of the present disclosure, the channel is a channel having a p-type conductivity, and the electrode has a metal work function value of less than about 4 eV.

In accordance with some embodiments of the present disclosure, the cap layer includes aluminum oxide, silicon oxide, or a combination thereof.

In accordance with some embodiments of the present disclosure, each of the first interface layer and the second interface layer includes a high-k dielectric material including titanium oxide, hafnium oxide, zirconium oxide, niobium oxide, cerium oxide, or combinations thereof.

In accordance with some embodiments of the present disclosure, the electrode includes platinum, ruthenium, palladium, tungsten, gold, aluminum, cobalt, copper, titanium, tantalum, zirconium, hafnium, or alloys thereof.

In accordance with some embodiments of the present disclosure, the electrode includes hafnium, thallium, arsenic, magnesium, uranium, lanthanum, scandium, thorium, lutetium, neodymium, gadolinium, yttrium, terbium, lithium, cerium, calcium, sodium, samarium, barium, strontium, europium, potassium, rubidium, caesium, or alloys thereof.

In accordance with some embodiments of the present disclosure, a method for manufacturing a semiconductor structure includes: forming a gate electrode on a substrate; forming a gate dielectric layer on the gate electrode; forming a channel disposed on the gate dielectric layer opposite to the gate electrode; and forming a drain unit and a source unit on the gate dielectric layer, the drain unit and the source unit being connected to the channel and spaced apart from each other by the channel, at least one of the drain unit and the source unit including an electrode and a tunnel layer disposed between the electrode and the channel so as to adjust a barrier height between the electrode and the channel.

In accordance with some embodiments of the present disclosure, the method for manufacturing a semiconductor structure further includes forming a cap layer on the channel.

In accordance with some embodiments of the present disclosure, the method for manufacturing a semiconductor structure further includes forming a first interface layer between the gate electrode and the gate dielectric layer.

In accordance with some embodiments of the present disclosure, the method for manufacturing a semiconductor structure further includes forming a second interface layer between the channel and the gate dielectric layer.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a gate electrode;
a gate dielectric layer disposed on the gate electrode;
a channel disposed on the gate dielectric layer opposite to the gate electrode; and
a drain unit and a source unit connected to the channel and spaced apart from each other by the channel, at least one of the drain unit and the source unit including:
an electrode; and
a tunnel layer disposed between the electrode and the channel so as to adjust a barrier height between the electrode and the channel.

2. The semiconductor structure according to claim 1, wherein the tunnel layer includes titanium oxide, hafnium oxide, zirconium oxide, gallium oxide, aluminum oxide, silicon oxide, or combinations thereof.

3. The semiconductor structure according to claim 1, wherein the at least one of the drain unit and the source unit further includes:
a conductive metal oxide layer disposed between the channel and the tunnel layer; and
a diffusion blocking layer disposed between the tunnel layer and the electrode.

4. The semiconductor structure according to claim 1, wherein the at least one of the drain unit and the source unit further includes:
a conductive metal oxide layer disposed on the tunnel layer opposite to the channel; and
a diffusion blocking layer disposed between the conductive metal oxide layer and the electrode.

5. The semiconductor structure according to claim 1, wherein the at least one of the drain unit and the source unit further includes:
a conductive metal oxide layer connected to the channel layer; and
a diffusion blocking layer disposed between the conductive metal oxide layer and the tunnel layer.

6. The semiconductor structure according to claim 3, wherein the at least one of the drain unit and the source unit further includes a first interface layer disposed between the conductive metal oxide layer and the tunnel layer.

7. The semiconductor structure according to claim 6, wherein the at least one of the drain unit and the source unit further includes a second interface layer disposed between the tunnel layer and the diffusion blocking layer.

8. A semiconductor structure, comprising:
a gate electrode;
a gate dielectric layer disposed on the gate electrode;
a channel disposed on the gate dielectric layer opposite to the gate electrode;
a cap layer disposed on the channel to prevent a contaminant from diffusing into the channel; and
a drain unit and a source unit connected to the channel and spaced apart from each other by the channel, at least one of the drain unit and the source unit including:
an electrode; and
a tunnel layer disposed between the electrode and the channel so as to adjust a barrier height between the electrode and the channel.

9. The semiconductor structure according to claim 8, further comprising a first interface layer disposed between the gate electrode and the gate dielectric layer.

10. The semiconductor structure according to claim 9, further comprising a second interface layer disposed between the channel and the gate dielectric layer.

11. The semiconductor structure according to claim 8, wherein the channel is a channel having an n-type conductivity, and the electrode has a metal work function value of greater than 3 eV.

12. The semiconductor structure according to claim 8, wherein the channel is a channel having a p-type conductivity, and the electrode has a metal work function value of less than 4 eV.

13. The semiconductor structure according to claim 8, wherein the cap layer includes aluminum oxide, silicon oxide, or a combination thereof.

14. The semiconductor structure according to claim 10, wherein each of the first interface layer and the second interface layer includes a high-k dielectric material including titanium oxide, hafnium oxide, zirconium oxide, niobium oxide, cerium oxide, or combinations thereof.

15. The semiconductor structure according to claim 11, wherein the electrode includes platinum, ruthenium, palladium, tungsten, gold, aluminum, cobalt, copper, titanium, tantalum, zirconium, hafnium, or alloys thereof.

16. The semiconductor structure according to claim 12, wherein the electrode includes hafnium, thallium, arsenic, magnesium, uranium, lanthanum, scandium, thorium, lutetium, neodymium, gadolinium, yttrium, terbium, lithium, cerium, calcium, sodium, samarium, barium, strontium, europium, potassium, rubidium, caesium, or alloys thereof.

17. A method for manufacturing a semiconductor structure, comprising:
forming a gate electrode on a substrate;
forming a gate dielectric layer on the gate electrode;
forming a channel disposed on the gate dielectric layer opposite to the gate electrode; and
forming a drain unit and a source unit on the gate dielectric layer, the drain unit and the source unit being connected to the channel and spaced apart from each other by the channel, at least one of the drain unit and the source unit including an electrode and a tunnel layer disposed between the electrode and the channel so as to adjust a barrier height between the electrode and the channel.

18. The method according to claim 17, further comprising forming a cap layer on the channel.

19. The method according to claim 18, further comprising forming a first interface layer between the gate electrode and the gate dielectric layer.

20. The method according to claim 19, further comprising forming a second interface layer between the channel and the gate dielectric layer.
